(19) United States
(12) Patent Application Publication
(10) Pub. No.: US 2012/0007510 A1
(43) Pub. Date: Jan. 12, 2012

(54) CONTROL MODULE WITH POWER SUPPLY DETECTION AND LAMP UTILIZING THE SAME

(76) Inventors: Alex Horng, Kaohsiung (TW); Kuan-Yin Hou, Kaohsiung (TW); Chung-Ken Cheng, Kaohsiung (TW); Ching-Ya Huang, Kaohsiung (TW); Li-Yang Lyu, Kaohsiung (TW)

(21) Appl. No.: 12/831,814

(22) Filed: Jul. 7, 2010

(51) Int. Cl. H05B 37/02; H03K 5/01

(52) U.S. Cl. 315/149; 315/307; 327/100

(57) ABSTRACT

A lamp with power supply detection includes a power supply unit, a control module and a lighting module. The power supply unit provides a direct current (DC) voltage. The control module is coupled to the power supply unit, receives and stores the DC power, and generates a control signal according to whether the DC power is terminated or regained. The lighting module is coupled to the power supply unit and the control module, receives the DC power and adjusts brightness of the lighting module according to the control signal.

### BACKGROUND OF THE INVENTION

1. Field of the Invention

The present invention generally relates to a control module with power supply detection and a lamp utilizing the same and, more particularly, to a control module that adjusts its output signal for switching brightness level of a lamp based on an ON/OFF switching of a power supply of the lamp.

2. Description of the Related Art

Light-emitting diodes (LED) have been widely adapted in various products (family lamps, LED TVs, traffic lights, flashlights, headlamps etc) due to advantages such as high efficiency, long service life and low power consumption and so on. Referring to FIG. 1, Taiwan Patent Number M376097 discloses a conventional lamp 9 and a light control method thereof. The lamp 9 includes a voltage dividing circuit 91, a lighting module 92 and a control circuit 93. The voltage dividing circuit 91 provides a driving voltage to the lighting module 92. The control circuit 93 is able to adjust brightness of the lighting module 92 by controlling the magnitude of the driving voltage. However, in this mechanism, an extra control unit controlling the control circuit 93 is required for a user to adjust the brightness of the lighting module 92. In addition, using such voltage dividing resistors (which constructs the voltage dividing circuit 91) may result in a waste of power, leading to a low efficiency of the lamp. Another drawback with the voltage dividing resistors is that the light of the lighting module 92 may have a slight change in color due to different current function of the LEDs.

In light of the above problems, it is desired to improve the conventional control module and the lamp.

### SUMMARY OF THE INVENTION

It is therefore the primary objective of this invention to provide a control module with power supply detection and a lamp utilizing the same. The control module controls brightness of the lamp according to whether a direct current (DC) of a power supply unit is terminated or regained, allowing the brightness of the lamp to adjust among multiple levels.

It is another objective of this invention to provide a control module with power supply detection and a lamp utilizing the same. The control module uses a stored energy of an energy-storing unit to maintain operation of a control unit thereof.

The invention discloses a lamp with power supply detection, including a power supply unit, a control module and a lighting module. The power supply unit provides a direct current (DC) voltage. The control module is coupled to the power supply unit, receives and stores the DC power, and generates a control signal according to whether the DC power is terminated or regained. The lighting module is coupled to the power supply unit and the control module, receives the DC power and adjusts brightness of the lighting module according to the control signal.

Furthermore, the invention discloses a control module with power supply detection, including an energy-storing unit, a detection unit and a monitoring unit. The energy-storing unit receives and stores a direct current (DC) voltage. The detection unit generates a detection signal according to whether the DC power is terminated or regained. The monitoring unit is coupled to the energy-storing unit and the power supply unit to receive the DC power and the detection signal, and generates a control signal according to the detection signal.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 shows a brightness adjustment circuit of a conventional lamp.

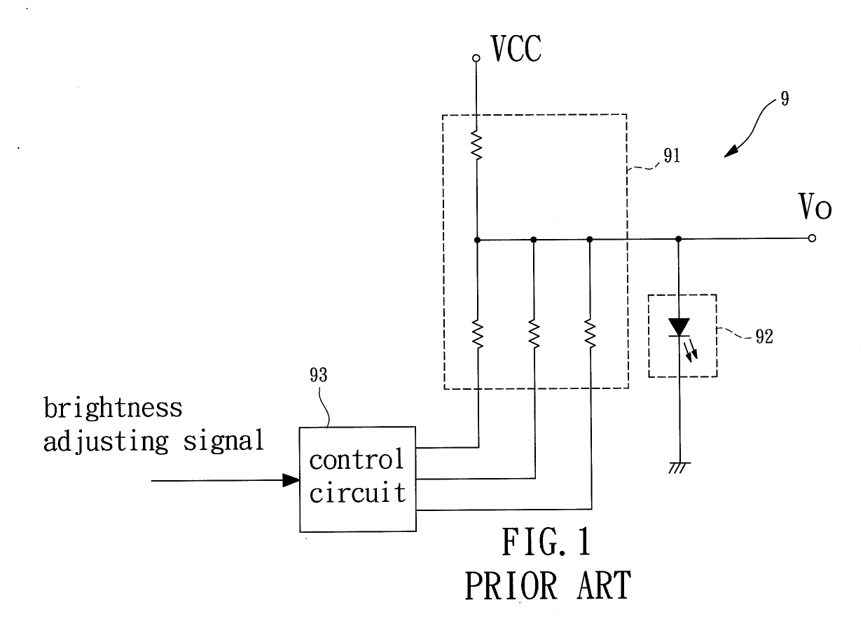

FIG. 2 shows a control module with power supply detection and a lamp using the control module according to a preferred embodiment of the invention.

FIG. 3 shows another implementation of the control module according to the preferred embodiment of the invention.

FIG. 4 shows a circuit diagram of a lighting unit having a buck circuit according to the preferred embodiment of the invention.

FIG. 5 shows a circuit diagram of a lighting unit having a boost circuit according to the preferred embodiment of the invention.

FIG. 6 shows a circuit diagram of a lighting unit having a flyback circuit according to the preferred embodiment of the invention.

FIG. 7 shows a circuit diagram of a lighting unit having a forward circuit according to the preferred embodiment of the invention.

In the various figures of the drawings, the same numerals designate the same or similar parts. Furthermore, when the term “first”, “second”, “third”, “fourth”, “inner”, “outer” “top”, “bottom” and similar terms are used hereinafter, it should be understood that these terms are reference only to the structure shown in the drawings as it would appear to a person viewing the drawings and are utilized only to facilitate describing the invention.

### DETAILED DESCRIPTION OF THE INVENTION

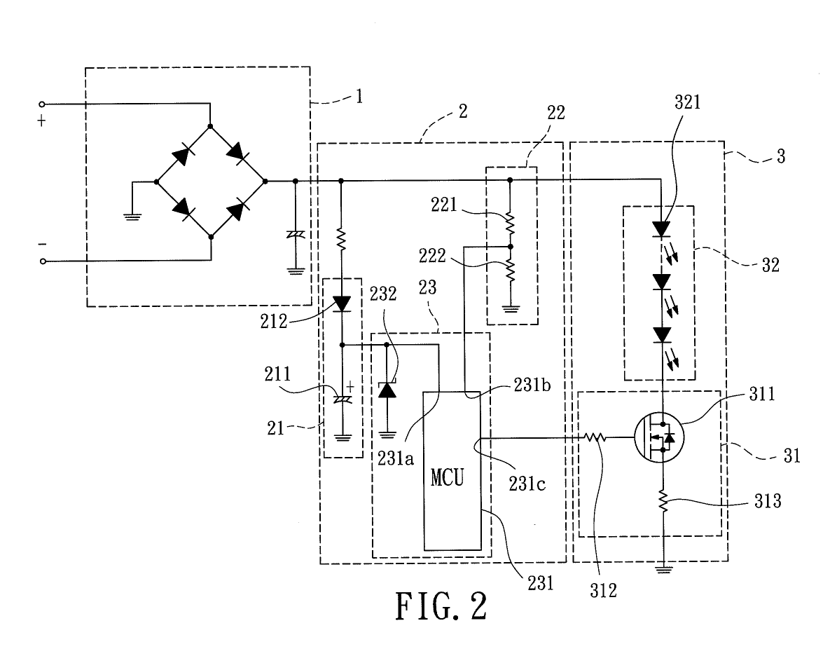

Referring to FIG. 2, a control module with power supply detection and a lamp using the control module are disclosed according to a preferred embodiment of the invention. The lamp comprises a power supply unit 1, a control module 2 and a lighting module 3. The power supply unit 1 is electrically connected to the control module 2 and the lighting module 3. The power supply unit 1 provides a direct current (DC) power to the control module 2 and the lighting module 3. The control module 2 is electrically connected to the lighting module 3 and outputs a control signal to the lighting module 3. The brightness of the lighting module 3 may be adjusted by the control signal of the lighting module 3.

Specifically, the power supply unit 1 preferably includes a rectifying unit for converting an alternating current (AC) voltage into the DC power supplied to the control module 2 and the lighting module 3. As shown in FIG. 2, the rectifying unit is preferably a full-bridged rectifier.

The control module 2 includes an energy-storing unit 21, a detection unit 22 and a monitoring unit 23. The energy-storing unit 21 and the detection unit 22 are electrically connected between the power supply unit 1 and the monitoring unit 23. When the power supply unit 1 supplies power normally, the energy-storing unit 21 may store and deliver the power to the monitoring unit 23. In the same time, the power supply unit 1 may keep providing power to the monitoring unit 23 for maintaining operation of the monitoring unit 23 when the power from the power supply unit 1 is terminated. The detection unit 22 generates and sends a detection signal to the monitoring unit 23 based on whether the power supply unit 1 supplies power as normal or not. The monitoring unit 23 is electrically connected to the lighting module 3 which, in turn, generates and sends the control signal to the lighting module 3 based on the detection signal.

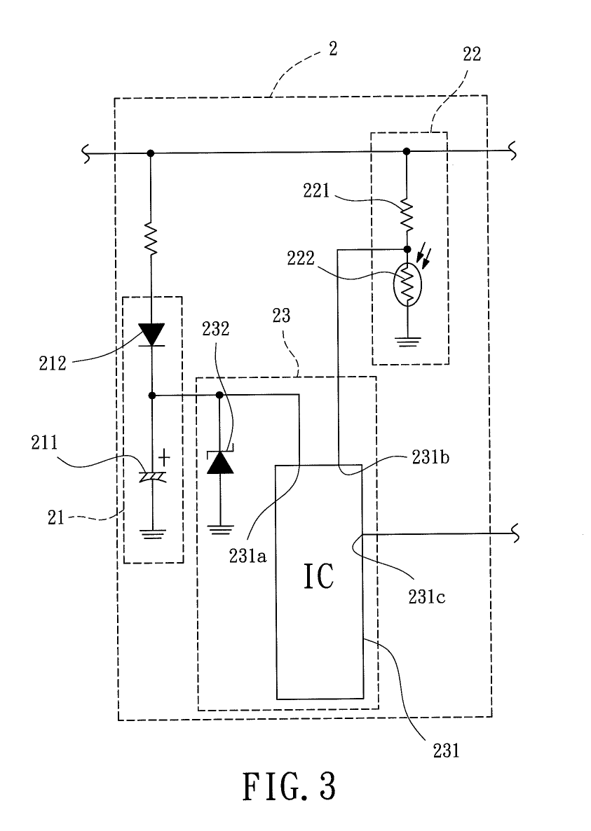

Specifically, the energy-storing unit 21 preferably includes a storage capacitor 211 and a diode 212 that are connected in series between the power supply unit 1 and a ground. The diode 212 is preferably connected between the storage capacitor 211 and the power supply unit 1 in series. The detection unit 22 preferably includes a first voltage dividing resistor 221 and a second voltage dividing resistor 222 that are connected in series between the power supply unit 1 and the ground. The first voltage dividing resistor 221 preferably has a larger resistance than the second voltage dividing resistor 222 so that the detection signal has a smaller magnitude. The monitoring unit 23 includes a control unit 231 having a power supply end 231a, a sensing end 231b and a command end 231c. The power supply end 231a is electrically connected to the energy-storing unit 21 to receive the power therefrom. Preferably, the power supply end 231a is electrically connected to a node where the storage capacitor 211 and the diode 212 are connected. The sensing end 231b is electrically connected to the detection unit 22 to receive the detection signal therefrom. Specifically, the sensing end 231b is connected to a node where the first voltage dividing resistor 221 and the second voltage dividing resistor 222 are connected. The command end 231c is electrically connected to the lighting module 3 and provides the control signal thereto. The control unit 231 may be a driving chip, a Micro Control Unit (MCU), a Field Programmable Gate Array (FPGA), a Complex Programmable Logic Device (CPLD) or an Application Specific Integrated Circuit (ASIC). Moreover, the monitoring unit 23 preferably includes a zener diode 232 connected between the power supply end 231a and the ground so that the monitoring unit 23 is protected from an extreme high voltage greater than a breakdown voltage of the zener diode 232. Referring to FIG. 3, another implementation of the detection unit 22 is shown. In this implementation, the first voltage dividing resistor 221 or the second voltage dividing resistor 222 is implemented as a photo resistor. In this implementation, the second voltage dividing resistor 222 is implemented as the photo resistor and the control unit 231 is implemented as an IC chip.

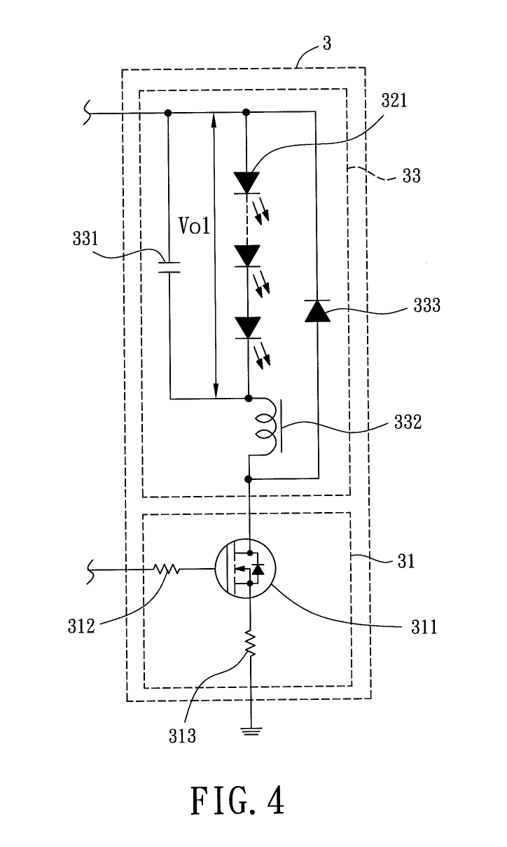

Referring to FIG. 2 again, the lighting module 3 includes a driving circuit 31 and a lighting unit 32 connected in series between the power supply unit 1 and the ground. The driving circuit 31 is electrically connected to the command end 231c of the control unit 231 to receive the control signal therefrom. Based on the control signal, currents passing through the lighting unit 32 may be controlled. Specifically, the driving circuit 31 preferably includes a power electronic switch 311 having a gate that is coupled to the command end 231c to receive the control signal therefrom. Based on the control signal, ON/OFF operation of the power electronic switch 311 may be controlled based on a voltage level of the control signal. The driving circuit 31 preferably includes a third resistor 312 and a fourth resistor 313. The third resistor 312 is electrically connected between the gate and the command end 231c, whereas the fourth resistor 313 is electrically connected to a source of the power electronic switch 311. The two resistors 312 and 313 protect the power electronic switch 311 from being damaged by an excessive high current. The lighting unit 32 preferably includes at least one LED 321 which emits light when a current passes through it. Alternatively, as shown in FIGS. 4 to 7, the at least one LED 321 may be implemented with a buck circuit, a boost circuit, a flyback circuit and a forward circuit to form other types of lighting units 33, 34, 35 and 36, respectively.

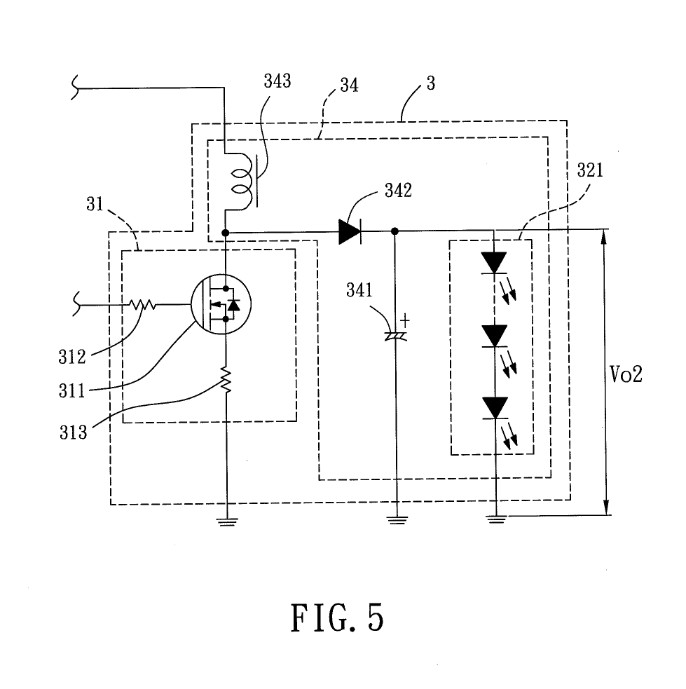

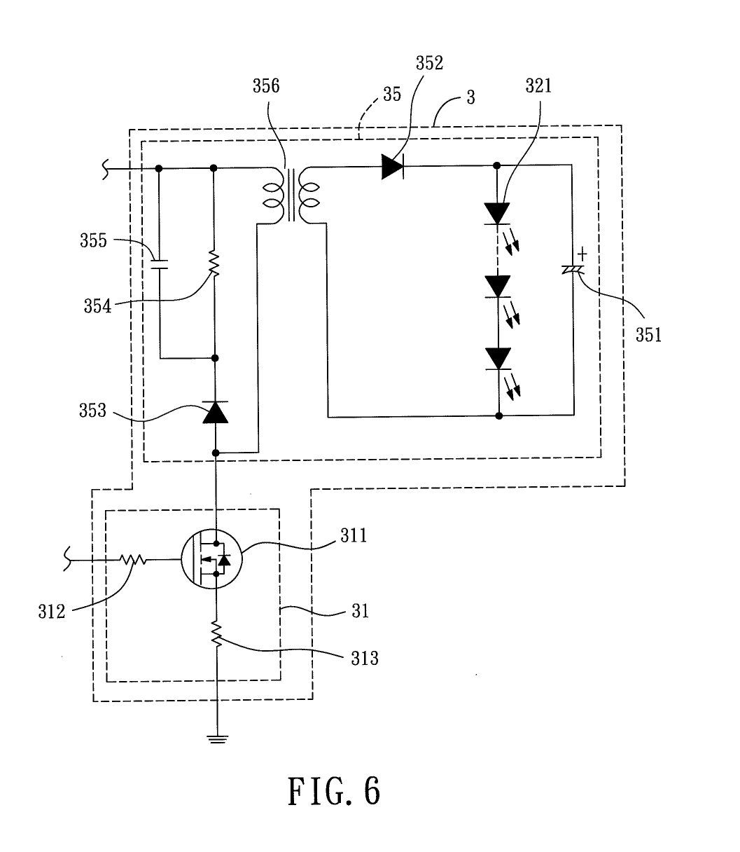

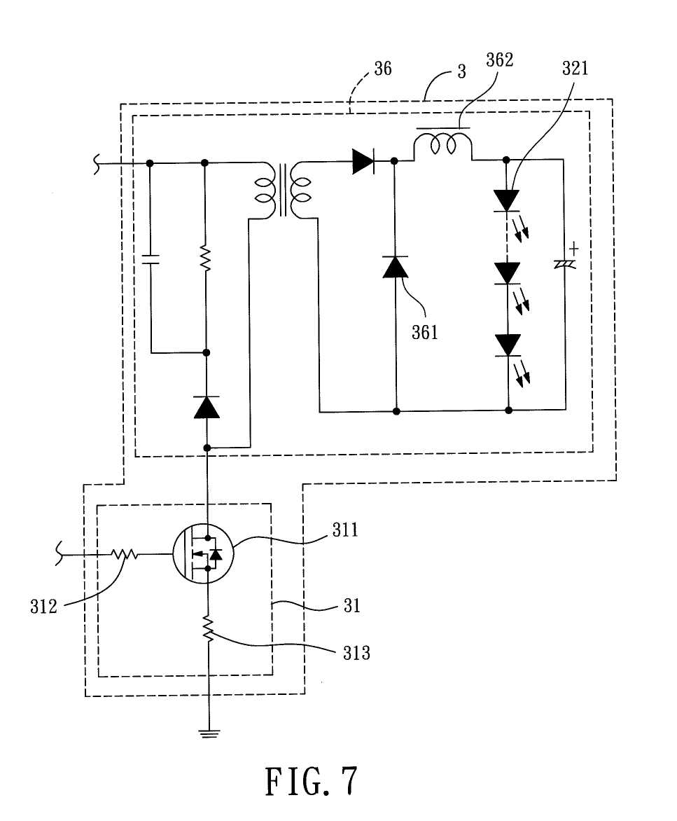

Specifically, referring to FIG. 4, based on the arrangements that a capacitor 331 is electrically connected to the at least one LED 321 in parallel and to an inductor 332, as well as that a diode 333 is connected between the capacitor 331 and the inductor 332, a voltage V_{O1} across the at least one LED 321 may be reduced. Referring to FIG. 5, the at least one LED 321 is electrically connected to a capacitor 341 in parallel, and to a diode 342 and an inductor 343 in series. In this arrangement, a voltage V_{O2}, across the at least one LED 321 may be boosted when the inductor 343 releases energy. In the lighting units 33 and 34, since input and output ends are not isolated from each other, the lighting units 33 and 34 are more suitable for use in a case where isolation between the input and output ends is not required. Referring to FIG. 6, the lighting unit 35 includes a capacitor 351 electrically connected to the at least one LED 321 in parallel, a first diode 352 electrically connected to the at least one LED 321 in series, and a second diode 353 electrically connected to a resistor 354 and a second capacitor 355 in series. The lighting unit 35 further includes a transformer 356 having a primary side electrically connected to the second diode 353, resistor 354 and the second capacitor 355, as well as a secondary side electrically connected to the first diode 352. In addition, the resistor 354 is electrically connected to the second capacitor 355 in parallel, and an anode of the second diode 353 is electrically connected to the driving circuit 31 of the lighting unit 35. Based on the arrangements, a voltage on the primary side of the transformer 356 may induce a higher or lower voltage on the secondary side of the transformer 356, achieving voltage reduction or boosting. Through the transformer 356, voltage separation between the primary and secondary sides may also be achieved. Referring to FIG. 7, the lighting unit 36 in FIG. 7 is differed from the lighting unit 35 in FIG. 6 by that the at least one LED 321 is electrically connected to an inductor 362 in series to form a series circuit, and a diode 361 is electrically connected to the series circuit in parallel. The diode 361 may be turned on when the power electronic switch 311 is switched off, improving the efficiency of the lighting unit 36. The diode 361 may preferably be a Schottky diode or a fly wheel diode to improve circuit efficiency. Based on the above description, functions of the control module and the lamp in the invention are described in detail below.

When the power supply unit 1 supplies power as normal, the detection signal of the detection unit 22 remains a standard voltage (such as 2.5V).

When the power supply unit 1 stops providing power, the detection signal of the detection unit 22 becomes a low voltage (such as 0V). Based on this, the voltage switching of the detection signal, regardless of switching from the standard voltage to the low voltage or from the low voltage to the standard voltage, may be detected by the control unit 231 via the sensing end 231b thereof. Based on the detected result, the magnitude, frequency and duty cycle of the control signal may be determined by the control unit 231. The control signal may be classified into a plurality of levels based on different magnitude, frequency or duty cycle. In addition, referring to FIG. 3, when the second voltage dividing resistor 222 is implemented as the photo resistor, the brightness of the lighting module 3 may be controlled by directly blocking the light of the photo resistor without terminating the power from the power supply unit 1. In other words, the detection signal will remain the standard voltage if the photo resistor receives the light as normal. On the contrary, the photo resistor will have higher resistance when blocked from the light, forcing the detection signal to turn into a high voltage (such as 5V). In this case where the photo resistor is used to replace the second voltage dividing resistor 222, the detection signal is switched between the high voltage and the low voltage.

Specifically, when the control signal is in one of the plurality of levels and the detection signal switches from the standard voltage to the low voltage in a specific timing, the control unit 231 immediately detects whether the detection signal switches from the low voltage back to the standard voltage within a predetermined period following the specific timing. If so, the control unit 231 switches the control signal to a next level. If not, the control unit 231 maintains the control signal in the current level. In this way, brightness of the lighting module 3 may be controlled. Alternatively, when the detection signal switches from the standard voltage to the high voltage in the specific timing, the control unit 231 may detect whether the detection signal switches from the high voltage back to the standard voltage within the predetermined period following the specific timing. If so, the control unit 231 switches the control signal to a next level. If not, the control unit 231 maintains the control signal in the current level.

For instance, assume that the predetermined period is 1 second and the control signal has four levels respectively corresponding to 25%, 50%, 75% and 100% of maximal brightness of the lighting module 3. In this case, assume that the control signal is currently in the level corresponding to 50% of the maximal brightness and that the detection signal switches from the low voltage back to the standard voltage within 1 second following the specific timing where the detection signal switches from the standard voltage to the low voltage, then the control signal will be switched to the next level corresponding to 75% of the maximal brightness of the lighting module 3. On the contrary, if the detection signal does not switch from the low voltage back to the standard voltage within 1 second following the specific timing, the control signal will remain in the current level corresponding to 50% of the maximal brightness of the lighting module 3. Although the detection signal is described to be switched between the standard voltage and the low voltage in the above example, one of ordinary skill in the art would readily appreciate that the detection signal may switch between the standard voltage and the high voltage to determine the level of the control signal, namely, determining the brightness of the lighting module 3. Based on the principle above, the brightness of the lighting module 3 may be switched among the four levels corresponding to 25%, 50%, 75% and 100% of maximal brightness of the lighting module 3, thus achieving the brightness adjustment of the lighting module 3.

When the control signal is classified into a plurality of levels based on different duty cycles thereof, the control unit 231 outputs a Pulse Width Modulation (PWM) signal to control the turned-on period of the driving circuit 31, thereby driving the lighting unit 32 by an adjustable current.

Although the invention has been described in detail with reference to its presently preferable embodiment, it will be understood by one of ordinary skill in the art that various modifications can be made without departing from the spirit and the scope of the invention, as set forth in the appended claims.

What is claimed is:

1. A lamp with power supply detection, comprising:
a power supply unit providing a DC power;
a control module coupled to the power supply unit, receiving and storing the DC power, and generating a control signal according to whether the DC power is terminated; and
a lighting module coupled to the power supply unit and the control module, receiving the DC power and adjusting brightness of the lighting module according to the control signal.

2. The lamp with power supply detection as claimed in claim 1, wherein the control module includes an energy-storing unit, a detection unit and a monitoring unit, the energy-storing unit is coupled to the power supply unit and the monitoring unit for receiving and storing the DC power of the power supply unit and for providing power to the monitoring unit, the detection unit generates a detection signal according to whether the DC power is terminated or regained, the monitoring unit is coupled to the detection unit to receive the detection signal and generates the control signal according to the detection signal.

3. The lamp with power supply detection as claimed in claim 2, wherein the energy-storing unit includes a storage capacitor and a diode connected in series between the power supply unit and the ground, and the monitoring unit is coupled to a node where the storage capacitor and the diode are connected.

4. The lamp with power supply detection as claimed in claim 2, wherein the detection unit includes a first voltage dividing resistor and a second voltage dividing resistor connected in series between the power supply unit and the ground, and the monitoring unit is coupled to a node where the first voltage dividing resistor and the second voltage dividing resistor are connected.

5. The lamp with power supply detection as claimed in claim 4, wherein the first voltage dividing resistor or the second voltage dividing resistor is a photo resistor.

6. The lamp with power supply detection as claimed in claim 2, wherein the monitoring unit includes a control unit having a power supply end, a sensing end and a command end, the power supply end is coupled to the energy-storing unit, the sensing end is coupled to the detection unit, and the command end is coupled to the lighting module.

7. The lamp with power supply detection as claimed in claim 6, wherein the monitoring unit further includes a zener diode connected between the power supply end and the ground.

8. The lamp with power supply detection as claimed in claim 1, wherein the lighting module includes a driving circuit and a lighting unit connected in series between the power supply unit and the ground.

9. The lamp with power supply detection as claimed in claim 8, wherein the lighting module includes at least one LED and one of a buck circuit, a boost circuit, a flyback circuit and a forward circuit.

10. The lamp with power supply detection as claimed in claim 6, wherein the control unit is a driving chip, a Micro Control Unit, a Field Programmable Gate Array, a Complex Programmable Logic Device or an Application Specific Integrated Circuit.

11. The lamp with power supply detection as claimed in claim 1, wherein the control module adjusts at least one of magnitude, frequency and duty cycle of the control signal outputted thereby.

12. A control module with power supply detection, comprising:
an energy-storing unit receiving and storing a DC power;
a detection unit generating a detection signal according to whether the DC power is terminated or regained; and
a monitoring unit coupled to the energy-storing unit and the detection unit to receive the DC power and the detection signal, and generating a control signal according to the detection signal.

13. The control module with power supply detection as claimed in claim 12, wherein the detection unit includes a first voltage dividing resistor and a second voltage dividing resistor connected in series, and the monitoring unit is coupled to a node where the first voltage dividing resistor and the second voltage dividing resistor are connected.

14. The control module with power supply detection as claimed in claim 13, wherein the first voltage dividing resistor or the second voltage dividing resistor is a photo resistor.

15. The control module with power supply detection as claimed in claim 12, wherein the energy-storing unit includes a storage capacitor and a diode connected in series, and the monitoring unit is coupled to a node where the storage capacitor and the diode are connected.

16. The control module with power supply detection as claimed in claim 12, wherein the monitoring unit includes a control unit having a power supply end, a sensing end and a command end, the power supply end is coupled to the energy-storing unit, the sensing end is coupled to the detection unit to receive the detection signal, and the command end outputs the control signal.

17. The control module with power supply detection as claimed in claim 16, wherein the control unit is a driving chip, a Micro Control Unit, a Field Programmable Gate Array, a Complex Programmable Logic Device or an Application Specific Integrated Circuit.

18. The control module with power supply detection as claimed in claim 12, wherein the monitoring unit adjusts at least one of magnitude, frequency and duty cycle of the control signal outputted thereby.

19. The control module with power supply detection as claimed in claim 16, wherein the monitoring unit further includes a zener diode connected between the power supply end and the ground.
